(19) United States
(12) Patent Application Publication
(10) Pub. No.: US 2012/0128019 A1
(43) Pub. Date: May 24, 2012

(54) MONOLITHICALLY INTEGRATED MULTI-WAVELENGTH HIGH-CONTRAST GRATING VCSEL ARRAY

(75) Inventors: Connie Chang-Hasnain, Palo Alto, CA (US); Bala Subrahmanyam Pesala, Chennai (IN); Vadim Karagodsky, Berkeley, CA (US)

(73) Assignee: THE REGENTS OF THE UNIVERSITY OF CALIFORNIA, Oakland, CA (US)

(21) Appl. No.: 13/298,531

(22) Filed: Nov. 17, 2011

Related U.S. Application Data
(63) Continuation of application No. PCT/US2010/036103, filed on May 26, 2010.
(60) Provisional application No. 61/181,586, filed on May 27, 2009.

(51) Int. Cl. H01S 5/343; H01S 5/183; H01L 21/02; H01S 5/187

(52) U.S. Cl. 372/45.01; 438/29; 257/E21.002

(57) ABSTRACT

Multiple-wavelength VCSEL array apparatus and method having a high contrast grating (HCG) mirror which can be implemented on a single substrate in which only the dimensions of the HCG (e.g., duty cycle or the period) need be changed to alter the wavelength of a given VCSEL in response to changing the reflectivity phase of the HCG mirror. The HCG can be defined by any desired lithographic process. By using a broadband HCG mirror a large wavelength span over 100 nm is provided, such as covering the entire C-band. The HCG multi-wavelength VCSEL array enables single-transverse mode emission and polarization control and scalability with respect to wavelength.

### CROSS-REFERENCE TO RELATED APPLICATIONS

This application a 35 U.S.C. §111(a) continuation of PCT international application number PCT/US2010/036103 filed on May 26, 2010, incorporated herein by reference in its entirety, which is a nonprovisional of U.S. provisional patent application Ser. No. 61/181,586 filed on May 27, 2009, incorporated herein by reference in its entirety. Priority is claimed to each of the foregoing applications.

The above-referenced PCT international application was published as PCT International Publication No. WO 2010/138524 on Dec. 2, 2010 and republished on Mar. 31, 2011, and is incorporated herein by reference in its entirety.

This application is related to U.S. patent application Ser. No. 12/779,248 filed on May 13, 2010, incorporated herein by reference in its entirety. This application is also related to PCT international patent application number PCT/US2010/034731 filed on May 13, 2010, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to VCSEL arrays, and more particularly to fabrication of multi-wavelength VCSEL arrays on a single substrate.

2. Description of Related Art

The increasing popularity of online video streaming content has been a major driving factor for high capacity data networks including local area networks (LANs) and fiber-to-the-home/fiber-to-the-desktop commonly referred to as FTTx applications. In addition, high speed optical interconnects operating at bandwidths above 1 Tb/sec are becoming increasingly attractive based on their low power consumption and compact size in comparison to electrical interconnects. Wavelength division multiplexing (WDM) offers an ideal way to leverage the high bandwidth of terabit optical fiber (>>1 Tb/sec) while using the existing low speed electronics operating at speeds close to 10 Gb/sec. For these applications monolithically integrated low cost multi-wavelength sources are particularly desirable. Vertical cavity surface emitting lasers (VCSELs) are an effective solution for multi-wavelength sources with benefits that include surface normal emission, low cost manufacturing, and wafer scale testing. Furthermore, multi-wavelength VCSEL sources may provide cost effective solutions for a wide range of applications including optical sensing of gases and displays.

Earlier techniques to fabricate monolithically integrated multi-wavelength VCSELs include using patterned substrates or surface regrowth. By patterning the substrate with lithographically-defined structures prior to the growth of the VCSEL a gradient arises in surface temperature which results in a change of layer thickness which alters the lasing wavelength in accord with the round-trip phase condition of the VCSEL cavity. Similarly, patterning of the substrate into a 2-D array of mesas of varying diameter gives rise to local chemical concentration gradients of gas species in a metal organic chemical vapor deposition (MOCVD) scheme and results in a change in the layer thickness of the VCSELs. Wavelength control to 45 nm is the best that could be achieved using this method.

The precise control of lasing wavelength using the above methods are very difficult to achieve due to the irregularity in temperature gradients in an MBE system and the complex fluid mechanics in an MOCVD system. At the present time, these problems are only circumvented by employing anodic oxidation of a GaAs spacer layer followed by MBE regrowth. This process requires a large number of fabrication steps, and as such is not readily scalable for large VCSEL arrays, and/or producing a large volume of VCSEL arrays.

Accordingly, a need exists for a VCSEL array apparatus and simple method of fabrication which overcomes the deficiencies of previously developed multi-wavelength VCSEL arrays and their fabrication methods.

### BRIEF SUMMARY OF THE INVENTION

Multi-wavelength VCSEL array apparatus and fabrication methods are described which incorporate a high-contrast grating (HCG) as at least one of the mirrors in the VCSEL. It will be appreciated that the high reflectivity exhibited by HCGs over a broad wavelength range, for example Δλ/λ of approximately 35%, makes them an effective alternative to the use of conventional distributed-Bragg reflectors (DBR). Using these teachings, the lasing wavelength of the VCSEL can be controlled over a very broad range (e.g., greater than approximately 100 nm) by varying the duty cycle and the period of the HCG, such as through lithography. Compared to earlier approaches for fabricating multi-wavelength VCSEL arrays, the inventive method provides an extremely simple one-step process which does not require modification of the traditional VCSEL process flow. In response to the scalability of HCG design with respect to wavelength, the technique is readily applicable at any wavelength range, including but not limited to 500 nm, 850 nm, 980 nm,1300 nm, or 1550 nm ranges. Furthermore, use of an HCG mirror enables single transverse-mode emission and polarization control within a VCSEL, which are very desirable attributes for real applications.

By way of example and not limitation, the high contrast grating can be defined lithographically using several techniques including, but not limited to, DUV lithography, e-beam, focused ion beam or nano imprinting techniques. The desired wavelength control is achieved by simply varying the duty cycle η or the period Λ of a properly designed HCG. Numerical simulations are described based on rigorous coupled-wave analysis (RCWA) to simulate the proposed HCG VCSEL. By using a broadband HCG as the mirror, a large wavelength span, such as greater than 100 nm, was demonstrated covering the entire C-band. Unlike other approaches, the use of an HCG mirror within multi-wavelength VCSEL arrays enables relatively large area single-transverse mode emission and polarization control (either TE or TM). The scalability of the HCG design with respect to wavelength also enables the applicability of this technique across any desired wavelength range.

The invention is amenable to being embodied in a number of ways, including but not limited to the following descriptions.

One embodiment of the invention is an apparatus for vertical cavity surface emission laser (VCSEL) output at multiple lasing wavelengths from an array of vertical cavities, comprising: (a) a first (e.g., bottom) mirror structure; (b) a plurality of vertical cavities within a vertical cavity array, in which each vertical cavity of the plurality of vertical cavities, disposed adjacent the first mirror structure; (c) an active layer within each vertical cavity having a plurality of quantum wells (e.g., InGaAlAs, or similar) configured for laser light generation; and (d) a high-contrast grating (HCG) (e.g., InP) disposed adjacent each vertical cavity and configured as a second mirror; wherein at least one high-contrast grating is fabricated with different lateral dimensions to vary the phase of reflectivity to support multiple lasing wavelengths in the vertical cavity array.

In different implementations, the first or second mirror may comprise the top mirror, with the remaining mirror comprising the bottom mirror. In at least one implementation the first mirror structure comprises a distributed Bragg reflector (DBR). In at least one implementation the first mirror structure is fabricated over a substrate comprising a semiconductor material, for example Indium Phosphide (InP), GaAs, GaN, sapphire, Si, or similar. In at least one implementation a tunnel junction is formed within each vertical cavity and is configured for removing the majority of p-doped materials. In at least one implementation the first mirror structure comprises a distributed Bragg reflector (DBR), such as having any desired number of layer pairs. In at least one implementation a plurality of vertical cavities are disposed over a shared first mirror layer. In at least one implementation the mirror structure comprises separate mirrors, over each of which are disposed a vertical cavity. In at least one implementation the apparatus is a GaN-based vertical cavity surface emission laser (VCSEL) array. In at least one implementation an electrical confinement layer is disposed adjacent the active region. In at least one implementation the electrical confinement layer comprises areas of ion implantation, a buried tunnel junction, and/or an oxide aperture. In at least one implementation a vertical resonator cavity is disposed over the electrical confinement layer.

In at least one implementation the HCG is configured for reflecting a first portion of the light back into each the vertical cavity at a controlled polarization, while a second portion of the light is output from the apparatus. In at least one implementation the high contrast grating (HCG) comprises a material selected from the group of III-V compounds, II-VI, compounds, Si, Ge, SiGe, ZnOx, or similar. In at least one implementation the high contrast grating (HCG) comprises a material selected from the group of compounds consisting of GaAlAs, GaAs, AlAs, InGaAlAs, InP, InAs, InGaAs, InAlAs, InGaAsP, InGaAlAsP, InGaN, InGaAlN, GaN, InGaAlAsN, GaAlSb, GaSb, AlSb, or similar. In at least one implementation an air gap, or low index material layer (e.g., refractive index less than two), is disposed between the high-contrast grating (HCG) and each vertical cavity. In at least one implementation a low index material (e.g., oxide) is disposed beneath the high-contrast grating (HCG) and over the vertical cavity.

In at least one implementation lasing wavelength is changed based on varying induced phase which occurs in response to configuring the high contrast grating (HCG) with respect to duty cycle η, and/or grating period Λ, or alternatively in response to configuring the HCG with respect to duty cycle η, grating period Λ, thickness t_{g}, or combinations thereof. In at least one implementation multiple lasing wavelengths are directed to wavelengths which range around 850 nm, 980 nm, 1300 nm, and 1550 nm. The apparatus is utilized for operation within an application selected from the group of applications including but not limited to high speed local area networks, fiber-to-the-home applications, high speed optical interconnects, optical sensing of gases, and display applications.

One embodiment of the invention is an apparatus for vertical cavity surface emission laser (VCSEL) output at multiple lasing wavelengths from an array of vertical cavities, comprising: (a) a first mirror structure; (b) a plurality of vertical cavities within a vertical cavity array, in which each vertical cavity of the plurality of vertical cavities, is disposed adjacent the first mirror structure; (c) an active layer within each vertical cavity having a plurality of quantum wells configured for laser light generation; and (d) a high-contrast grating (HCG) disposed upon each vertical cavity and configured as a second mirror; (e) a low index region disposed between the high-contrast grating (HCG) and each vertical cavity; wherein at least one high-contrast grating is fabricated with different values of either duty cycle η, grating period Λ, thickness t_{g}, or combinations thereof, to vary the phase of reflectivity for providing multiple lasing wavelengths in the vertical cavity array.

One embodiment of the invention is a method of fabricating a multi-wavelength array of vertical-cavity surface emitting laser (VCSELs), comprising: (a) fabricating a plurality of first mirrors (e.g., distributed Bragg reflector (DBR) mirrors, or HCG mirrors) upon a substrate; (b) fabricating a plurality of VCSEL body structures, having a current aperture and an active region, adjacent the first mirrors, with the proximal end of each of the plurality of VCSEL body structures adjacent each of the first mirrors; and (c) fabricating a plurality of high-contrast gratings, wherein each high-contrast grating from the plurality of high-contrast gratings is configured as a second mirror disposed adjacent to the distal end of each of the plurality of VCSEL body structures; wherein one or more of the plurality of high-contrast gratings is fabricated with different lateral dimensions configured for varying the phase of reflectivity to support different lasing wavelengths.

In at least one implementation, a sacrificial layer is etched away from beneath the HCG to form a sub-grating space of low index material.

The present invention provides a number of beneficial elements which can be implemented either separately or in any desired combination without departing from the present teachings.

An element of the invention is a multi-wavelength VCSEL array.

Another element of the invention is a VCSEL array having a plurality of cavities for emitting light at different wavelengths.

Another element of the invention is a VCSEL array in which each VCSEL uses a high contrast grating (HCG) as a mirror (e.g., top and/or bottom).

Another element of the invention is an HCG VCSEL array in which the HCG of different VCSELs are configured with different dimensions, preferably lateral dimensions, to vary the phase of reflectivity and thus direct emissive output to different operating wavelengths.

A still further element of the invention is a VCSEL array which can be utilized in a variety of applications including but not limited to high speed local area networks, fiber-to-the-home applications, high speed optical interconnects, optical sensing of gases, display applications, and combinations thereof.

Further elements of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic of a high-contrast grating (HCG) structure used according to an element of the present invention.

FIG. 2 is a schematic of a VCSEL array having high-contrast grating (HCG) top mirrors shown according to an embodiment of the present invention.

FIG. 3 is a schematic of a VCSEL having high-contrast grating (HCG) top mirrors shown according to an embodiment of the present invention.

FIG. 4 is a schematic of an HCG VCSEL array in which the top-mirror HCG dimensions are varied to control wavelength according to an embodiment of the present invention.

FIGS. 5A and 5B are graphs of HCG wavelength response for two HCGs implemented with different lateral dimensions according to an element of the present invention.

FIGS. 6A and 6B are graphs of HCG wavelength response based on period and grating width according to an element of the present invention.

FIGS. 7A and 7B are graphs of field intensity of the cavity and active region of a MW HCG VCSEL according to an element of the present invention.

FIG. 8 is a graph of confinement factor of the MW HCG VCSEL array as a function of wavelength according to an element of the present invention.

FIG. 9 is a schematic of a VCSEL array having a high-contrast grating

(HCG) as one of the mirrors according to an embodiment of the present invention.

FIG. 10 is a flowchart of multi-wavelength VCSEL fabrication steps according to an element of the present invention.

### DETAILED DESCRIPTION OF THE INVENTION

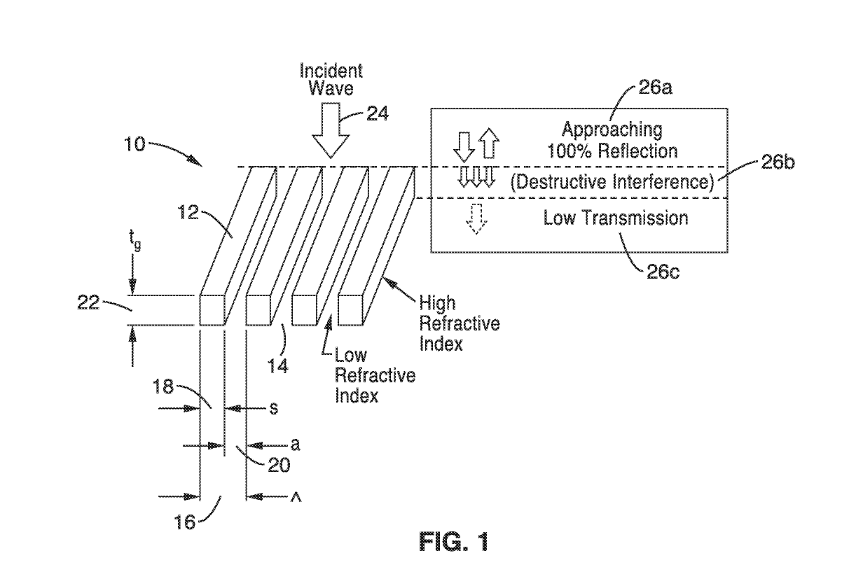

Referring more specifically to the drawings, for illustrative purposes the present invention is embodied in the apparatus generally shown in FIG. 1 through FIG. 10. It will be appreciated that the apparatus may vary as to configuration and as to details of the parts, and that the method may vary as to the specific steps and sequence, without departing from the basic concepts as disclosed herein. Furthermore, elements represented in one embodiment as taught herein are applicable without limitation to other embodiments taught herein, and combinations with those embodiments and what is known in the art.

1. Principles of High-Contrast Grating.

FIG. 1 illustrates an example embodiment 10 of an HCG which is utilized in a VCSEL as a high-reflectivity mechanism according to the invention. A semiconductor material 12 is shown as bar segments which have a high refractive index nᵣ which is greater than two, and preferably greater than three. In the embodiment shown the material of the bar segments has a refractive index of approximately 3.5. The grating bars are surrounded 14 by a low index medium, such as air or an oxide having a refractive index less than two. The grating period 16 Λ is shown which comprises bar width S 18 and inter-bar gap 20. It should be appreciated that duty cycle η is defined as the ratio of the width S of the high index material to grating period κ. Grating thickness 22 t_{g} is shown, such as in response to the thickness of a layer from which the HCG is etched.

When a wave is incident 24 on the grating, its energy is coupled into several eigenmodes of the HCG. These modes propagate through the grating at different phase velocities. For certain HCG designs, the exiting modes (including their reflections) interfere destructively 26b at the bottom of the grating interface, resulting in very low levels of coupling into a transmitted plane wave and very low transmission 26c through the grating, and which provides high levels of reflection 26a approaching 100%.

Consequently, a light beam incident on a periodic grating, as shown, is reflected and transmitted into multiple diffraction orders. In response to the use of a subwavelength grating, in which the grating period is less than the wavelength (Λ21 λ) all higher diffraction orders are evanescent in the air except for the zeroeth order. For optimally selected grating parameters, the destructive interference between the directly transmitted wave and the Bragg transmitted wave leads to extremely high reflectivity. The HCG grating can be configured to be extremely broadband and provide high reflectivity as a result of the high index contrast which exists between the gratings and its low index surroundings. The physical parameters that control the reflectivity and the bandwidth of the grating are grating period (κ), thickness (t_{g}), and duty cycle (η).

2. Principles of Multi-wavelength VCSEL Array.

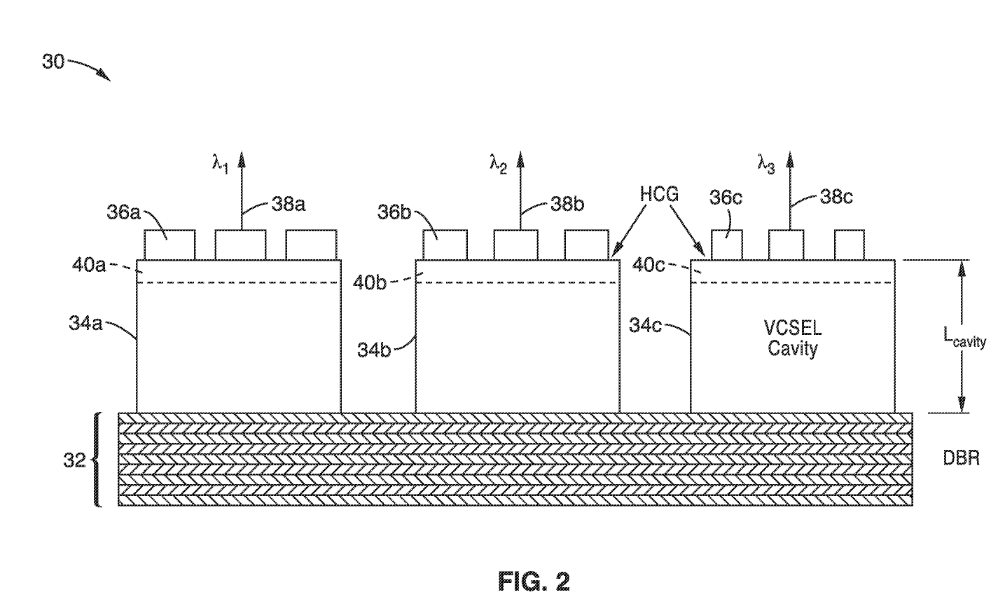

FIG. 2 illustrates an example embodiment 30 of a multi-wavelength VCSEL array showing the main principles of controlling lasing wavelength using HCGs. It should be appreciated that although the different embodiments herein show arrays with a specific number of VCSEL structures, VCSEL arrays can be implemented with any desired number of VCSEL structures without departing from the teachings of the present invention. The VCSEL array 30 is shown fabricated over a common (shared) bottom mirror 32 (first mirror), with VCSEL cavity structures 34a, 34b, and 34c (details of which are shown here for simplicity of illustration). It should be appreciated that the VCSEL cavity incorporates an active region, a current aperture, and preferably one or more heat and current spreaders. Over each of the cavity structures is fabricated HCG top mirrors 36a, 36b, 36c which are configured for adapting the operating wavelengths 38a, 38b, 38c of one or more of the VCSELs within the array. Low index material regions 40a, 40b, and 40c are shown disposed beneath each of the gratings. It is to be appreciated, that although the HCG mirror is shown as the top mirror (second mirror) in this example, the HCG could also in principle be used as the bottom mirror (first mirror) or both top and bottom mirrors. In the example shown, the bottom mirror preferably comprises a DBR 32 having a desired number of layer pairs. By varying the duty cycle or the grating period of the HCG mirror (36a, 36b, and/or 36c), the phase of the HCG is altered which in turn causes a change in the lasing wavelength. Due to the broadband high reflectivity of the HCG, the wavelength can be controlled over a large span, such as over approximately 100 nm.

The high-contrast grating is preferably used as the top mirror while the DBR preferably serves as the bottom mirror, although the positions of the two mirrors can be switched without departing from the present teachings. The lasing wavelength (λ₁) of the VCSEL cavity is determined by the round-trip phase condition, for example given by 4πnL_{cavity}/λ₁+φ_{HCG}+φ_{DBR}=2mπ, where n is the refractive index of the cavity, L_{cavity} is the cavity length, φ_{HCG} and φ_{DBR} are the phases induced by the HCG and DBR respectively. The induced phase φ_{HCG} can be varied by controlling the dimensions of the HCG, and preferably the lateral dimensions, and more particularly the duty cycle (η) and/or the grating period (Λ) of the HCG, such as lithographically. Although varying HCG thickness t_{g} alters phase response, and can be varied toward controlling wavelength, this is preferably kept constant for the sake of simplicity of fabrication. Changes to the induced phase directly translate to a change in the lasing wavelength. It is worth emphasizing that the thickness of the HCG layer is preferably kept constant to simplify fabrication. However, it should be appreciated that embodiments can be implemented according to the invention in which the thickness of the HCG is modified. Due to the broadband high reflectivity nature of the HCG, the lasing wavelength can be controlled over a large span (>30 nm).

3. Design of Multi-wavelength VCSEL Array.

A design methodology is described below for a VCSEL array operating near a center wavelength of 1550 nm. It should be appreciated that although the discussion is about an example embodiment of a 1550 nm VCSEL, individual VCSELs and multi-wavelength VCSEL arrays according to the present invention can be implemented across any desired range of wavelength. The VCSEL cavity structures used in simulations of the device are similar to that previously demonstrated for other high-speed 1550 nm VCSEL designs, with the epitaxial top mirror being replaced by a HCG structure.

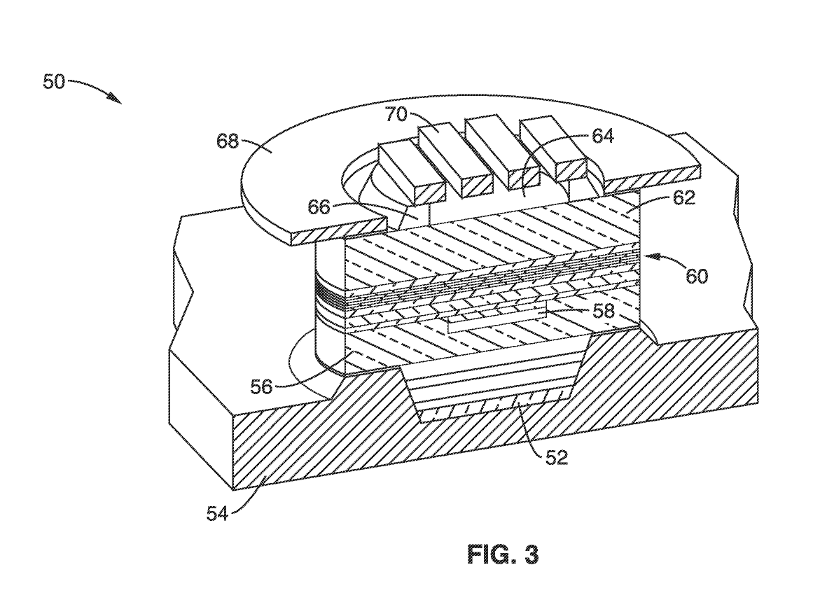

FIG. 3 illustrates an example embodiment of a HCG VCSEL 50 configured for fabrication within a multi-wavelength VCSEL array. The VCSEL device is shown fabricated with a separate bottom mirror 52, exemplified as being recessed within a substrate 54. The bottom mirror 52 in this example comprises several pairs (e.g., 40) of bottom DBR fabricated within a recess within an InP substrate. By way of example, the HCG VCSEL is configured for operation at 1550 nm. This implementation of the device comprises a conventional dielectric DBR as bottom mirror 52, a lower portion 56 of the VCSEL cavity serving as heat and current spreader including a current aperture 58, an active region 60, and an upper portion 62 of the VCSEL cavity.

An air gap 64, or other low index material layer, is shown disposed beneath an HCG top-reflector 70. The top mirror (out-coupling mirror) comprises an HCG which is preferably lithographically fabricated from a semiconductor material, such as Indium Phosphide (InP). It should be appreciated that the HCG may be alternatively selected from a variety of materials, such as one selected from the group of IIIV compounds, II-VI compounds, Si, Ge, SiGe, ZnOx, or similar. Any material of a refractive index greater than approximately two can serve as the HCG material. More particularly, materials can be selected from materials including GaAlAs, GaAs, AlAs, InGaAlAs, InP, InAs, InGaAs, InAlAs, InGaAsP, InGaAlAsP, InGaN, InGaAlN, GaN, InGaAlAsN, GaAlSb, GaSb, AlSb, and so forth and combinations thereof. The remainder of the VCSEL can be fabricated from any desired material combination capable of supporting lasing at the desired wavelengths. An HCG support structure 66 is shown surrounding air gap 64 and supporting the HCG. A contact structure 68 is shown surrounding the support. It will be appreciated that support 66 can be implemented in a variety of alternative ways without departing from the invention, such as from a layer of low index material (e.g., oxide) which provides both a supportive structure and low index portion of the cavity.

The active region 60 preferably comprises multiple quantum wells, such as preferably InGaAlAs quantum wells, or other materials, examples of which include but are not limited to GaAlAs, InGaAsP, InGaAlP, InGaAlN, and/or similar materials and combinations thereof. Current confinement is preferably achieved by an aperture formed by a buried tunnel junction, placed at the minimum of the optical field, for achieving a stable single mode operation. The HCG layer is preferably fabricated on top of a sacrificial layer which by way of example is preferably etched away afterwards to provide high index contrast between the HCG and the surrounding layer. In one alternative implementation, the top two layers could also be fabricated from another low index material with a refractive index less than two, such as SiO₂, and another semiconductor, such as Si, as the HCG,

4. Multi-wavelength HCG-VCSEL Array Design.

The VCSEL wavelength is determined by the round-trip 2π phase condition (Eq. 1) as in any Fabry-Perot cavity:

$$4 π \frac{{L}_{Cavity}}{{λ}_{Lasing}} + {φ}_{HCG} + {φ}_{DBR} = 2 π m \qquad ( 1 )$$

In the above equation, L_{Cavity} is the physical length of the cavity, λ_{Lasing} is the lasing wavelength, φ_{HCG} and φ_{DBR} are the reflectivity phases of the HCG and DBR mirrors, respectively, with m as an integer value specifying the wavelength multiple (e.g., any integer multiple of 2π yields same lasing wavelength). Consequently, to attain a large wavelength range in λ_{Lasing} with the same epitaxy, that is the same L_{cavity} (φ_{DBR} being relatively insensitive to λ_{Lasing}), a design of HCG whose φ_{HCG} can be substantially modified in response to changes in the grating period and duty cycle. It was found in this case that by using a thicker HCG to facilitate a longer propagation length for the eigenmodes, the destructive interference condition can be achieved (to yield a high reflectivity) with a larger wavelength dependence in phase. This leads to a possibility of significantly changing λ_{Lasing} using only moderate changes in HCG lateral dimensions. This design is highly desirable for fabricating post-epitaxy MW VCSEL arrays in a controllable fashion with an especially large wavelength tuning range.

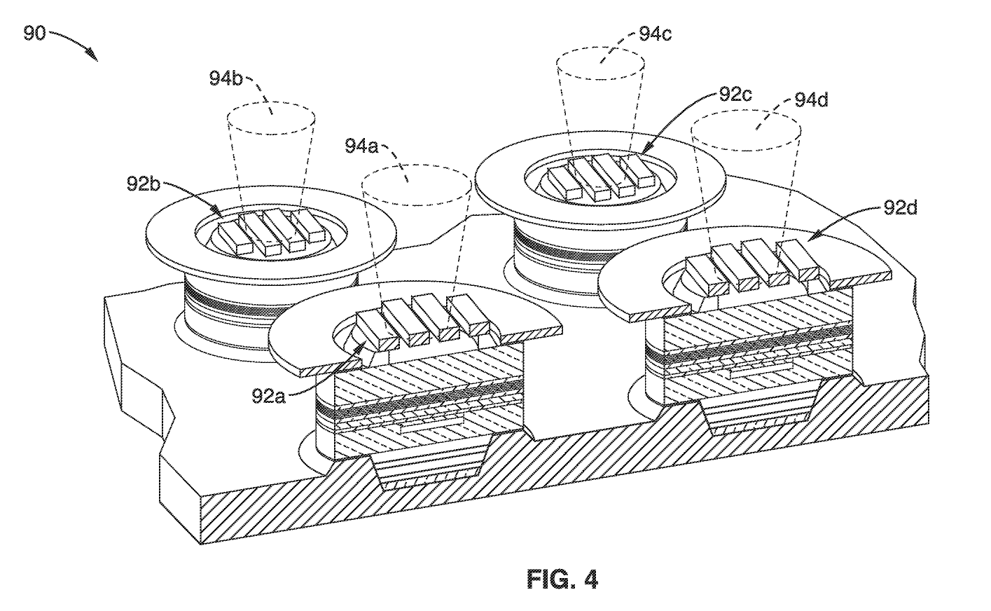

FIG. 4 illustrates an example embodiment 90 of multi-wavelength (MW) HCG VCSEL array using separate bottom mirrors on a substrate. The lasing wavelength of each VCSEL output 94a, 94b, 94c, 94d, is modified in response to changing the lateral dimensions of the HCG 92a, 92b, 92c and 92d, which control the reflectivity phase. According to these teachings, a multi-wavelength VCSEL array can be readily fabricated utilizing this wavelength tuning paradigm.

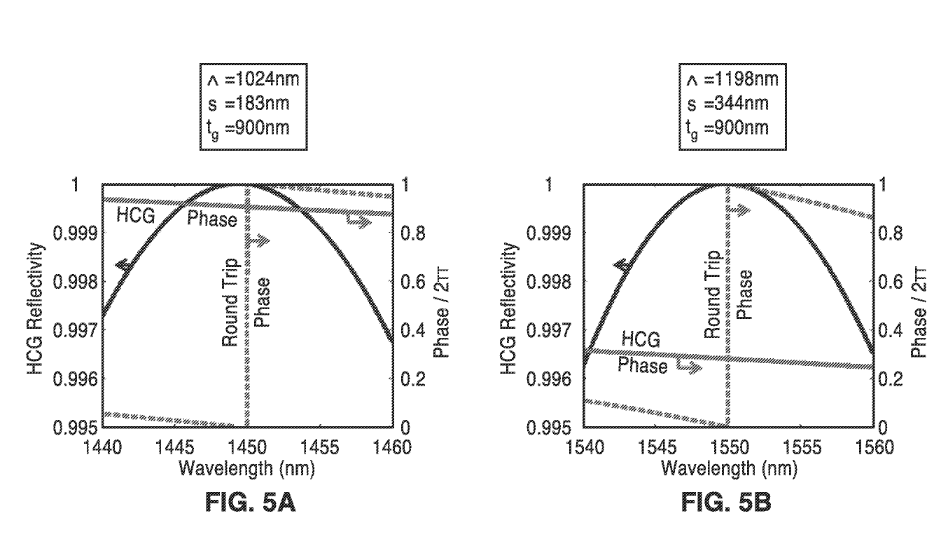

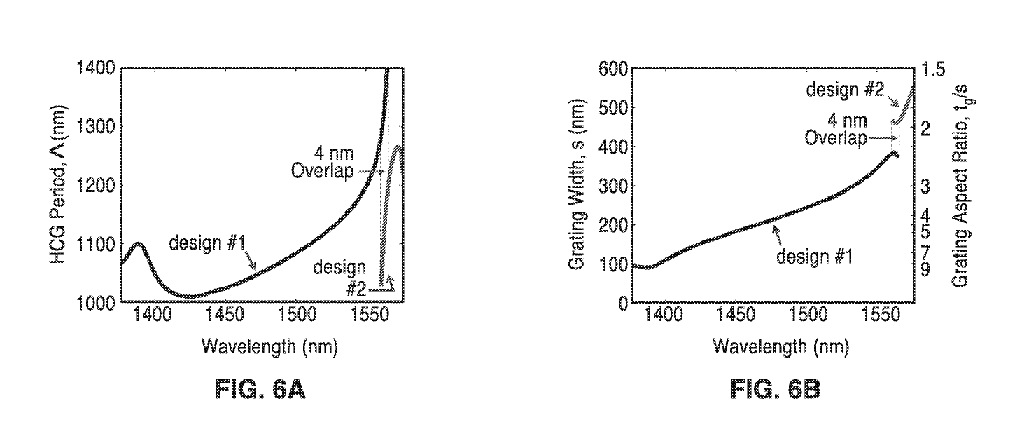

FIG. 5A and FIG. 5B and FIG. 6A and FIG. 6B are graphs of simulated results of two VCSEL grating arrangements. It should be appreciated that a reasonable HCG thickness of only 900 nm is sufficiently thick for providing a wavelength tuning range in excess of 100 nm, as presented in the graphs.

In FIG. 5A and FIG. 5B reflectivity and phase are shown for each of two HCG mirror designs to facilitate lasing at two different wavelengths. In FIG. 5A HCG lateral dimensions were Λ=1024 nm, s=183 nm with t_{g}=900 nm which maximized HCG reflectivity at 1450 nm. In FIG. 5B HCG lateral dimensions were Λ=1198 nm, s=344 nm with t_{g}=900 nm which maximized HCG reflectivity at 1550 nm. The HCG thickness is identical in both designs, as the HCGs were patterned on the same layer in the implementation to simplify fabrication. To alter the wavelength response of the VCSEL in this embodiment the lateral dimensions of the HCG, in particular period Λ and bar width S are varied. The use of thicker HCGs can facilitate larger potential phase shifts. In this implementation, a reasonable HCG thickness of 900 nm has been selected to support considerable changes in HCG phase in response to small changes in the lateral dimensions to provide a wide variation of lasing wavelengths. High quality factor is achieved by high reflectivity's, such as greater than approximately 99.5%, of HCG and DBR mirrors.

The optimized HCG dimensions are presented in FIG. 5A and FIG. 5B as a function of lasing wavelength, which demonstrate an expected wavelength tuning range in excess of 100 nm. All these dimensions satisfy the phase condition in Eq. (1) and correspond to very high HCG reflectivity (above 99.9%). The difference between the curves shown in FIGS. 5A and 5B is in response to φ_{HCG} in Eq. (1) which is determined by the lateral dimensions of the HCG.

In FIG. 6A and FIG. 6B wavelength is shown in response to changes in grating period Λ in FIG. 6A, and grating width S in FIG. 6B for a first and second design depicted by the differently marked lines in the graph. The use of these different lateral dimensions, while retaining an otherwise identical VCSEL structure, results in satisfying the round trip 2 π phase condition in Eq. 1 at two different wavelengths (1450 nm and 1550 nm). By optimizing lateral HCG dimensions according to the invention, a collection of dimensions has been found suitable for lasing at every wavelength between 1376 nm and 1576 nm, all with the same HCG thickness of 900 nm.

Additionally, the HCG reflectivity is maintained well above 99.9% at the lasing wavelengths, which is also necessary for achieving a high Q cavity with low mirror losses. In some VCSEL designs, reflectivity of 99.9% might be too high for light extraction. In those cases, the present invention allows the reflectivity to be adjusted as desired, such as to be slightly less (e.g. approximately 99.5%).

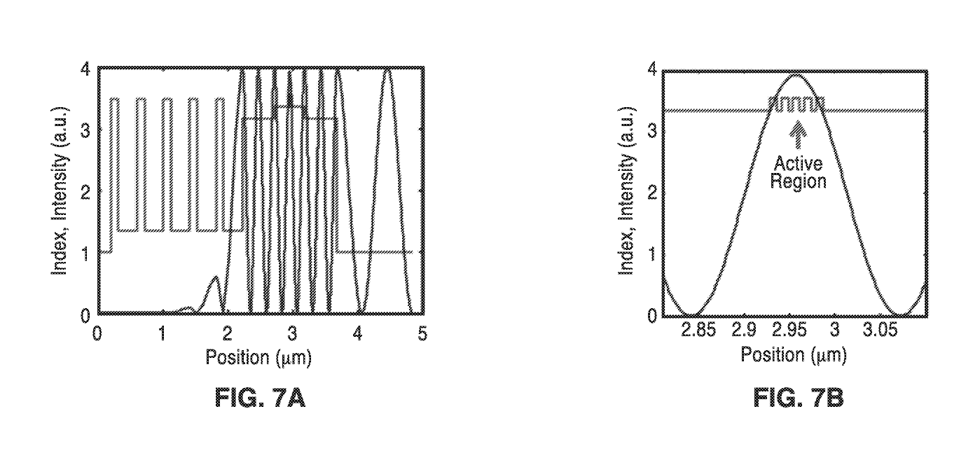

FIG. 7A and FIG. 7B are graphs of field intensity for the cavity and within the active region of the MW HCG VCSEL. The profile of the cavity of a MW HCG VCSEL structure is overlaid on the refractive index of the materials at 1570 nm in FIG. 7A. In FIG. 7B the field profile is shown for the active region. The graphs indicate that for some wavelengths, more than one choice of HCG dimensions will facilitate lasing. A wavelength window of 4 nm was found at which two different HCG designs are suitable for lasing. This overlap window between two different HCG designs is necessary to make sure that the wavelength tuning range is continuous, such as devoid of wavelength gaps, at which no design would operate. In this way, when one of the designs can no longer be pushed to higher wavelengths, the design can switch to a second HCG design (with different dimensions) and extend the tuning range even further. It is considered that further optimization will reveal that a chain of three or more HCG designs in some VCSEL structures, can provide an even larger tuning range. In order to readily fabricate the HCG designs, special attention was focused on the optimization process to only use HCG dimensions which are well within the specification of current lithography techniques, as indicated by the relatively small grating aspect ratios shown in FIG. 6B.

5. Results from VCSEL Cavity Simulation.

In order to verify the influence of the HCG phase tuning on the standing cavity wave and the confinement factor of the VCSEL, transfer matrix calculations were performed. The graphs of FIG. 7A-7B show the standing cavity wave at 1570 nm with the index profile overlaid for comparison, demonstrating a good overlap of the quantum wells with the field in the optical cavity.

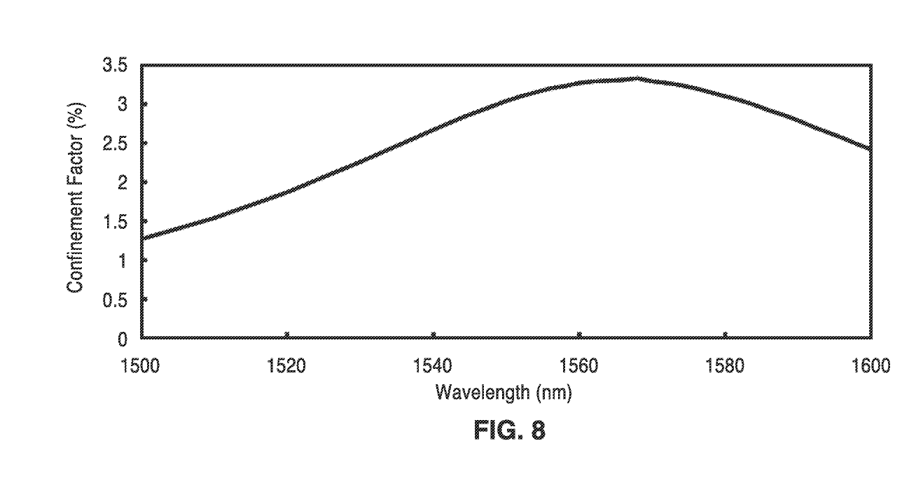

FIG. 8 is a graph of estimated confinement factor as a function of wavelength for various wavelengths from 1500 nm to 1600 nm for the HCG MW VCSEL array. It will be seen from the graph that over the 32 nm of wavelength range (1550 nm to 1582 nm) the confinement factor remains over 90% of its peak value. The confinement was calculated by integrating the field in the active region and dividing by the integral of the total field in the VCSEL structure (excluding the HCG). In response to the above the lateral confinement was estimated to be one. Over an optical bandwidth of 32 nm, corresponding to the bandwidth of the entire C-band, the so-called “erbium-window”, the confinement factor is still over 90% of its peak value, indicating that all C-band wavelengths could be addressed by variation of lateral HCG dimensions, while keeping fairly uniform device performance. Since the HCG dimensions depicted in FIG. 5A-5B and the confinement factors in FIG. 8 show robust performance of the structure across a very large wavelength range, the tuning range is perhaps largely determined by the gain bandwidth of the active region. Although, an embodiment of VCSEL operating at 1550 nm was discussed, separate VCSELs at a desired wavelength, and multi-wavelength VCSEL arrays of any wavelength can be fabricated according to this method.

6. Alternative Embodiment HCG VCSEL.

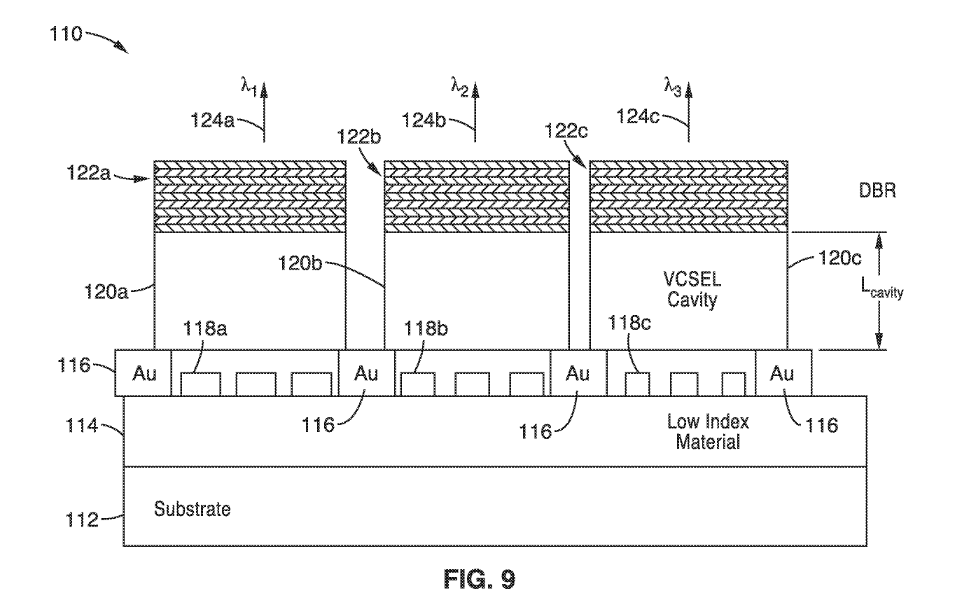

FIG. 9 illustrates an example embodiment 110 of another VCSEL utilizing an HCG as at least one of the mirrors in the VCSEL. In this embodiment, the body of the VCSEL is “inverted” from what is seen in FIG. 2 with respect to the substrate. A substrate 112 is shown upon which is disposed a low index material 114. Supports 116 are shown disposed over the low index material layer (or segments), for separating the remainder of the VCSEL body. It should be appreciated that a low index material covering the HCG could be utilized in place of the supports, toward supporting the remainder of the VCSEL structure, leaving the HCG entirely encapsulated in the low index material. Grating structures 118a, 118b, 118c of high index material are shown fabricated over the low index material as a first mirror. In this embodiment, each of the gratings are shown having different lateral dimensions to support different lasing wavelengths. VCSEL cavity structures 120a, 120b, and 120c are shown fabricated on supports 116. A second mirror 122a, 122b, 122c for each VCSEL structure is shown comprising a DBR mirror with a plurality of pairs of material (shown), or another high contrast grating (HCG) as desired. Three different output wavelengths 124a, 124b, and 124c are shown being emitted by the three VCSELs which only need to differ with respect to the lateral dimensions of their respective gratings.

7. VCSEL Fabrication Summary.

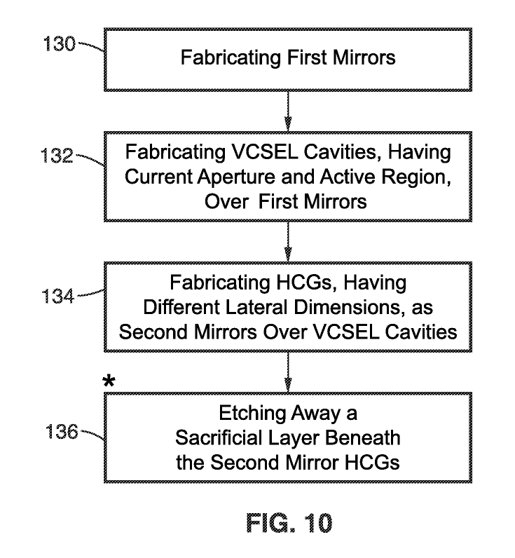

FIG. 10 illustrates an embodiment of a method for fabricating a multi-wavelength array of vertical-cavity surface emitting lasers (VCSELs). A first mirror is fabricated 130, which in one preferred embodiment comprises a distributed Bragg grating (DBR) having a plurality of layers, (e.g., 40 pairs). VCSEL cavities are formed 132 over the first mirror. Within the VCSEL cavities are at least a current aperture and active region. The active region preferably comprises multiple quantum wells. A buried tunnel junction, oxide confined region or ion implant may be used for achieving current and/or optical confinement in the active region. Other elements may be incorporated within the VCSEL cavity, including an intermediate mirror (e.g., DBR mirror with few layer pairs) and additional elements to provide heat sinking, current spreading, optical or electrical confinement, other elements and combinations thereof. Over each VCSEL cavity is formed a second mirror 134, shown fabricated as a high-contrast grating (HCG). The lateral dimensions of these HCGs are configured and/or modified to control the output wavelength from the VCSELs. Fabrication of the HCG preferably comprises an etching process to form the bar segments of the HCG. Preferably, the VCSEL optionally incorporates a sacrificial layer beneath the HCG layer, which is etched away 136 beneath the HCG to provide an air gap of a fixed depth or a depth of a desired thickness. It should be appreciated that either or both of the mirrors in the VCSEL can be fabricated using the HCG mirrors whose dimensions are wavelength tuned according to aspects of the present invention.

From the discussion herein, it can be seen that a multi-wavelength HCG VCSEL array apparatus and method are taught in which the wavelength range can be established in response to merely varying the lateral dimensions of the HCG. The HCG layer thickness, as well as all remaining VCSEL parameters, can remain constant for all devices, in order to facilitate a fabrication flow which is compatible with epitaxy. Use of this VCSEL structure enables a wavelength variable mechanism within the array which is based solely on lithography, facilitating a very simple fabrication flow. The predicted wavelength range exceeds 100 nm. Furthermore, the entire C-band could be easily accommodated using this type of VCSEL array design, enabling a new type of cost-effective WDM source. Due to the scalability of the HCG design with respect to wavelength, the technique is readily applicable at any wavelength range such as 500 nm, 850 nm, 980 nm, 1300 nm, and so forth.

It should be appreciated that although the technique allows variation of the VCSEL wavelength solely in response to changing HCG dimensions, which has many practical benefits, it is not limited to this type of implementation. In particular, the changing of HCG dimensionality for changing induced phase response, can be utilized in combination with other differentiation in the VCSEL structure as desired toward supporting a wider range of wavelengths or differing applications. In addition, changes to the HCG dimensions could also be utilized as a fine tuning mechanism if other VCSEL process variations cannot be as well controlled.

Furthermore, the teachings described herein can be implemented in combination with various other VCSEL control methods without limitation, with the following example being provided by way of example and not limitation. The size of individual segments within the HCG can be varied in order to provide a lensing action for additional optical containment. The air gap (or other low refractive material) spacing beneath the HCG, can be varied from one VCSEL to another, such as in response to changing the vertical etch depth. The air gap beneath the HCG can be varied in response to flexing or otherwise changing the position of the HCG to actively vary the air gap depth. It will also be appreciated that the segments of the HCG can be varied according to any known techniques.

From the description herein, it will be further appreciated that the invention can be embodied in various ways, which include but are not limited to the following.

1. An apparatus for vertical cavity surface emission laser (VCSEL) output at multiple lasing wavelengths from an array of vertical cavities, comprising: a first mirror structure; a plurality of vertical cavities within a vertical cavity array, in which each vertical cavity of said plurality of vertical cavities, is disposed adjacent said first mirror structure; an active layer within each vertical cavity having a plurality of quantum wells configured for laser light generation; a high-contrast grating (HCG) disposed adjacent each vertical cavity and configured as a second mirror; wherein at least one said high-contrast grating is fabricated with different lateral dimensions to vary the phase of reflectivity to support multiple lasing wavelengths in the vertical cavity array.

2. The apparatus according to embodiment 1, wherein said first mirror structure is fabricated over a substrate.

3. The apparatus according to embodiment 1, wherein said first mirror structure comprises a distributed Bragg reflector (DBR).

4. The apparatus according to embodiment 1, wherein said substrate comprises Indium Phosphide (InP), GaAs, GaN, sapphire or Si.

5. The apparatus according to embodiment 1, wherein said high-contrast grating (HCG) is configured for reflecting a first portion of the light back into each said vertical cavity at a controlled polarization, while a second portion of the light is output from said apparatus.

6. The apparatus according to embodiment 1, wherein each vertical cavity is configured with a tunnel junction for removing the majority of p-doped materials.

7. The apparatus according to embodiment 1, wherein said first mirror structure comprises a first mirror layer over which are disposed a plurality of vertical cavities.

8. The apparatus according to embodiment 1, wherein said first mirror structure comprises a plurality of separate first mirrors, over each of which are disposed a vertical cavity.

9. The apparatus according to embodiment 1, wherein said apparatus comprises an InP, GaAs, Si, GaN, sapphire, or GaSb based vertical cavity surface emission laser (VCSEL) array.

10. The apparatus according to embodiment 1, wherein said quantum wells comprise InGaAlAs, GaAlAs, InGaAsP, InGaAlP and/or InGaAlN.

11. The apparatus according to embodiment 1, further comprising an electrical confinement layer disposed adjacent said active region.

12. The apparatus according to embodiment 11, wherein said electrical confinement layer comprises areas of ion implantation.

13. The apparatus according to embodiment 11, wherein said electrical confinement layer comprises a buried tunnel junction.

14. The apparatus according to embodiment 11, wherein said electrical confinement layer comprises an oxide aperture.

15. The apparatus according to embodiment 11 further comprising a vertical resonator cavity disposed over said electrical confinement layer.

16. The apparatus according to embodiment 1, further comprising an air gap disposed between said high-contrast grating (HCG) and each vertical cavity.

17. The apparatus according to embodiment 1, further comprising a low index material layer, with refractive index less than two, disposed between said high-contrast grating (HCG) and each vertical cavity.

18. The apparatus according to embodiment 1, wherein said high contrast grating comprises a material having a refractive index greater than approximately two.

19. The apparatus according to embodiment 1, wherein said high contrast grating (HCG) comprises a material selected from the group of IIIV compounds, II-VI, compounds, Si, Ge, SiGe, and ZnOx.

20. The apparatus according to embodiment 1, wherein said high contrast grating (HCG) comprises a material selected from the group of compounds consisting of GaAlAs, GaAs, AlAs, InGaAlAs, InP, InAs, InGaAs, InAlAs, InGaAsP, InGaAlAsP, InGaN, InGaAlN, GaN, InGaAlAsN, GaAlSb, GaSb, and AlSb.

21. The apparatus according to embodiment 1, wherein the lasing wavelength is changed based on varying induced phase which occurs in response to configuring the high contrast grating (HCG) with respect to duty cycle η, and/or grating period Λ.

22. The apparatus according to embodiment 1, wherein the lasing wavelength is changed based on varying induced phase which occurs in response to configuring the HCG with respect to duty cycle η, grating period Λ, thickness t_{g}, or combinations thereof.

23. The apparatus according to embodiment 1, wherein said multiple lasing wavelengths are configured for wavelengths which range around 500 nm, 850 nm, 980 nm, 1300 nm, and 1550 nm.

24. The apparatus according to embodiment 1, wherein said apparatus is utilized for operation within an application selected from the group of applications consisting of high speed local area networks, fiber-to-the-home applications, high speed optical interconnects, optical sensing of gases, and display applications.

25. An apparatus for vertical cavity surface emission laser (VCSEL) output at multiple lasing wavelengths from an array of vertical cavities, comprising: a first mirror structure; a plurality of vertical cavities within a vertical cavity array, in which each vertical cavity of said plurality of vertical cavities, is disposed adjacent said first mirror structure; an active layer within each vertical cavity having a plurality of quantum wells configured for laser light generation; a high-contrast grating (HCG) disposed adjacent each vertical cavity and configured as a second mirror; a low index region disposed between said high-contrast grating (HCG) and each vertical cavity; wherein at least one said high-contrast grating is fabricated with different values of duty cycle η, grating period Λ, thickness t_{g}, or combinations thereof, to vary the phase of reflectivity for providing multiple lasing wavelengths in the vertical cavity array.

26. A method of fabricating a multi-wavelength array of vertical-cavity surface emitting laser (VCSELs), comprising: fabricating a plurality of first mirrors; fabricating a plurality of VCSEL body structures, having a current aperture and an active region, adjacent said first mirrors, with the proximal end of each of said plurality of VCSEL body structures adjacent each of said first mirrors; and fabricating a plurality of high-contrast gratings, wherein each high-contrast grating from said plurality of high-contrast gratings is configured as a second mirror disposed adjacent to the distal end of each of said plurality of VCSEL body structures; wherein one or more of said plurality of high-contrast gratings is fabricated with different lateral dimensions configured for varying the phase of reflectivity to support different lasing wavelengths.

27. The method according to embodiment 26, wherein said first mirror comprises a Distributed Bragg Reflector (DBR) mirror, or another High Contrast Grating (HCG) mirror.

28. The method according to embodiment 26, further comprising the step of etching away a sacrificial layer from beneath said HCG of each of said second mirrors to form a sub-grating space of low index material.

29. The method according to embodiment 26, further comprising the step of fabricating an electrical confinement layer adjacent said active region.

30. The method according to embodiment 29, wherein said electrical confinement layer is formed by ion implantation.

31. The method according to embodiment 29, wherein said electrical confinement layer is formed by the use of a buried tunnel junction.

32. The method according to embodiment 29, wherein said electrical confinement layer is formed by an oxide aperture.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An apparatus for vertical cavity surface emission laser (VCSEL) output at multiple lasing wavelengths from an array of vertical cavities, comprising:
a first mirror structure;
a plurality of vertical cavities within a vertical cavity array, in which each vertical cavity of said plurality of vertical cavities, is disposed adjacent said first mirror structure;
an active layer within each vertical cavity having a plurality of quantum wells configured for laser light generation; and
a high-contrast grating (HCG) disposed adjacent each vertical cavity and configured as a second mirror;
wherein at least one said high-contrast grating is fabricated with different lateral dimensions to vary the phase of reflectivity to support multiple lasing wavelengths in the vertical cavity array.

2. The apparatus recited in claim 1, wherein said first mirror structure is fabricated over a substrate.

3. The apparatus recited in claim 1, wherein said first mirror structure comprises a distributed Bragg reflector (DBR).

4. The apparatus recited in claim 1, wherein said substrate comprises Indium Phosphide (InP), GaAs, GaN, sapphire or Si.

5. The apparatus recited in claim 1, wherein said high-contrast grating (HCG) is configured for reflecting a first portion of the light back into each said vertical cavity at a controlled polarization, while a second portion of the light is output from said apparatus.

6. The apparatus recited in claim 1, wherein each vertical cavity is configured with a tunnel junction for removing the majority of p-doped materials.

7. The apparatus recited in claim 1, wherein said first mirror structure comprises a first mirror layer over which are disposed a plurality of vertical cavities.

8. The apparatus recited in claim 1, wherein said first mirror structure comprises a plurality of separate first mirrors, over each of which are disposed a vertical cavity.

9. The apparatus recited in claim 1, wherein said apparatus comprises an InP, GaAs, Si, GaN, sapphire, or GaSb based vertical cavity surface emission laser (VCSEL) array.

10. The apparatus recited in claim 1, wherein said quantum wells comprise InGaAlAs, GaAlAs, InGaAsP, InGaAlP and/or InGaAlN.

11. The apparatus recited in claim 1, further comprising an electrical confinement layer disposed adjacent said active region.

12. The apparatus recited in claim 11, wherein said electrical confinement layer comprises areas of ion implantation.

13. The apparatus recited in claim 11, wherein said electrical confinement layer comprises a buried tunnel junction.

14. The apparatus recited in claim 11, wherein said electrical confinement layer comprises an oxide aperture.

15. The apparatus recited in claim 11, further comprising a vertical resonator cavity disposed over said electrical confinement layer.

16. The apparatus recited in claim 1, further comprising an air gap disposed between said high-contrast grating (HCG) and each vertical cavity.

17. The apparatus recited in claim 1, further comprising a low index material layer, with refractive index less than two, disposed between said high-contrast grating (HCG) and each vertical cavity.

18. The apparatus recited in claim 1, wherein said high contrast grating comprises a material having a refractive index greater than approximately two.

19. The apparatus recited in claim 1, wherein said high contrast grating (HCG) comprises a material selected from the group of III-V compounds, II-VI, compounds, Si, Ge, SiGe, and ZnOx.

20. The apparatus recited in claim 1, wherein said high contrast grating (HCG) comprises a material selected from the group of compounds consisting of GaAlAs, GaAs, AlAs, InGaAlAs, InP, InAs, InGaAs, InAlAs, InGaAsP, InGaAlAsP, InGaN, InGaAlN, GaN, InGaAlAsN, GaAlSb, GaSb, and AlSb.

21. The apparatus recited in claim 1, wherein the lasing wavelength is changed based on varying induced phase which occurs in response to configuring the high contrast grating (HCG) with respect to duty cycle η, and/or grating period Λ.

22. The apparatus recited in claim 1, wherein the lasing wavelength is changed based on varying induced phase which occurs in response to configuring the HCG with respect to duty cycle η, grating period Λ, thickness t_{g}, or combinations thereof.

23. The apparatus recited in claim 1, wherein said multiple lasing wavelengths are configured for wavelengths which range around 500 nm, 850 nm, 980 nm, 1300 nm, and 1550 nm.

24. The apparatus recited in claim 1, wherein said apparatus is utilized for operation within an application selected from the group of applications consisting of high speed local area networks, fiber-to-the-home applications, high speed optical interconnects, optical sensing of gases, and display applications.

25. An apparatus for vertical cavity surface emission laser (VCSEL) output at multiple lasing wavelengths from an array of vertical cavities, comprising:
a first mirror structure;
a plurality of vertical cavities within a vertical cavity array, in which each vertical cavity of said plurality of vertical cavities, is disposed adjacent said first mirror structure;
an active layer within each vertical cavity having a plurality of quantum wells configured for laser light generation;
a high-contrast grating (HCG) disposed adjacent each vertical cavity and configured as a second mirror;
a low index region disposed between said high-contrast grating (HCG) and each vertical cavity;
wherein at least one said high-contrast grating is fabricated with different values of duty cycle η, grating period Λ, thickness t_{g}, or combinations thereof, to vary the phase of reflectivity for providing multiple lasing wavelengths in the vertical cavity array.

26. A method of fabricating a multi-wavelength array of vertical-cavity surface emitting laser (VCSELs), comprising:
fabricating a plurality of first mirrors;
fabricating a plurality of VCSEL body structures, having a current aperture and an active region, adjacent said first mirrors, with the proximal end of each of said plurality of VCSEL body structures adjacent each of said first mirrors; and
fabricating a plurality of high-contrast gratings, wherein each high-contrast grating from said plurality of high-contrast gratings is configured as a second mirror disposed adjacent to the distal end of each of said plurality of VCSEL body structures;
wherein one or more of said plurality of high-contrast gratings is fabricated with different lateral dimensions configured for varying the phase of reflectivity to support different lasing wavelengths.

27. The method recited in claim 26, wherein said first mirror comprises a Distributed Bragg Reflector (DBR) mirror, or another High Contrast Grating (HCG) mirror.

28. The method recited in claim 26, further comprising the step of etching away a sacrificial layer from beneath said HCG of each of said second mirrors to form a sub-grating space of low index material.

29. The method recited in claim 26, further comprising the step of fabricating an electrical confinement layer adjacent to said active region.

30. The method recited in claim 29, wherein said electrical confinement layer is formed by ion implantation.

31. The method recited in claim 29, wherein said electrical confinement layer is formed as a buried tunnel junction.

32. The method recited in claim 29, wherein said electrical confinement layer is formed as an oxide aperture.
